(19) United States
(12) Patent Application Publication
(10) Pub. No.: US 2022/0250192 A1
(43) Pub. Date: Aug. 11, 2022

(54) LASER PROCESSING APPARATUS

(71) Applicant: DISCO CORPORATION, Tokyo (JP)

(72) Inventor: Kentaro IIZUKA, Tokyo (JP)

(21) Appl. No.: 17/649,414

(22) Filed: Jan. 31, 2022

(30) Foreign Application Priority Data
Feb. 5, 2021 (JP) 2021-017183

(51) Int. Cl. B23K 26/70; B23K 26/06; B23K 26/08

(52) U.S. Cl. CPC B23K 26/705; B23K 26/0665; B23K 2101/40; B23K 26/0648; B23K 26/0643; B23K 26/0853

(57) ABSTRACT

A laser processing apparatus includes a chuck table configured to hold a workpiece, a laser beam irradiating unit having a condenser configured to condense and apply a laser beam to the workpiece held on the chuck table, a moving unit configured to move the chuck table and a condensing point of the laser beam relative to each other, a measuring unit configured to measure a beam profile of the laser beam; and a control unit configured to control each constituent element. The measuring unit is disposed adjacent to the chuck table so as to have a light receiving surface parallel with a holding surface of the chuck table.

### BACKGROUND OF THE INVENTION

### Field of the Invention

The present invention relates to a laser processing apparatus.

### Description of the Related Art

A laser processing apparatus is known which applies a laser beam along planned dividing lines set on a workpiece such as a semiconductor wafer in order to form the workpiece into individual pieces by dividing the workpiece (see Japanese Patent Laid-Open No. 2003-320466 and Japanese Patent No. 3408805). In such a laser processing apparatus, an unintended beam shape at a processing point at which the laser beam is condensed and applied to the workpiece may adversely affect a processing result. Thus, work of checking a beam shape is performed by using a beam profiler in advance before processing. For example, a laser processing apparatus is disclosed which captures the laser beam from a predetermined position on an optical path, and measures the laser beam (see Japanese Patent Laid-Open No. 2001-077046).

### SUMMARY OF THE INVENTION

However, there is a problem of inviting an increase in size of the apparatus when a large-sized measuring instrument such as the beam profiler is incorporated in the apparatus as in the laser processing apparatus of Japanese Patent Laid-Open No. 2001-077046. Accordingly, there is, for example, a method of performing measurement with the beam profiler temporarily mounted on a table holding the workpiece without the beam profiler being incorporated in the apparatus. However, making the laser beam incident on the profiler while paying attention to interference with constituent elements of the apparatus is very difficult, and is therefore time consuming and is also dangerous work.

It is accordingly an object of the present invention to provide a laser processing apparatus that makes it possible to measure a beam shape easily and safely while suppressing an increase in size of the apparatus.

In accordance with an aspect of the present invention, there is provided a laser processing apparatus including a chuck table having a holding surface configured to hold a workpiece, a laser beam irradiating unit having a condenser configured to condense and apply a laser beam to the workpiece held on the chuck table, a moving unit configured to move the chuck table and a condensing point of the laser beam relative to each other, a measuring unit configured to measure a beam profile of the laser beam, and a control unit configured to control each of the units, the measuring unit being disposed adjacent to the chuck table so as to have a light receiving surface parallel with the holding surface of the chuck table.

Preferably, the control unit includes a storage section configured to store a position of the laser beam applied to the light receiving surface, a comparing section configured to compare the position of the laser beam, the position being stored in the storage section, with a position of the laser beam measured in predetermined timing, and a notifying section configured to notify a warning when the position of the laser beam, the position being compared by the comparing section, is changed by a predetermined value or more.

Preferably, the laser processing apparatus further includes a Z-axis direction moving unit configured to move the measuring unit in a Z-axis direction as a direction perpendicular to the light receiving surface.

Preferably, the measuring unit is located at a retreat position at which a surface on which the laser beam is incident is located below an upper surface of the chuck table during non-measurement, and the measuring unit is located at a measurement position at which the surface on which the laser beam is incident is located above the upper surface of the chuck table during measurement.

The laser processing apparatus according to the present invention makes it possible to measure a beam shape easily and safely while suppressing an increase in size of the apparatus.

The above and other objects, features and advantages of the present invention and the manner of realizing them will become more apparent, and the invention itself will best be understood from a study of the following description and appended claims with reference to the attached drawings showing a preferred embodiment of the invention.

### BRIEF DESCRIPTION OF THE DRAWINGS

FIG. 1 is a perspective view illustrating an example of a configuration of a laser processing apparatus according to an embodiment;

FIG. 2 is a schematic diagram illustrating a general configuration of a laser beam irradiating unit of the laser processing apparatus illustrated in FIG. 1; and

FIG. 3 is a perspective view illustrating a general configuration of a measuring unit of the laser processing apparatus illustrated in FIG. 1.

### DETAILED DESCRIPTION OF THE PREFERRED EMBODIMENT

An embodiment of the present invention will hereinafter be described in detail with reference to the drawings. The present invention is not limited by contents described in the following embodiment. In addition, constituent elements described in the following include constituent elements readily conceivable by those skilled in the art and essentially identical constituent elements. Further, configurations described in the following can be combined with each other as appropriate. In addition, various omissions, replacements, or modifications of configurations can be performed without departing from the spirit of the present invention.

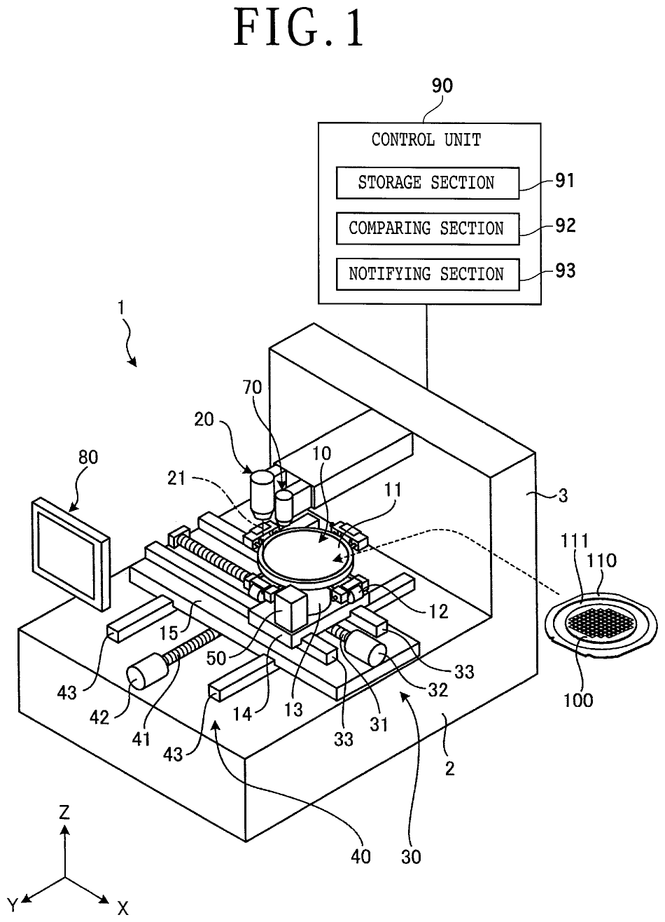

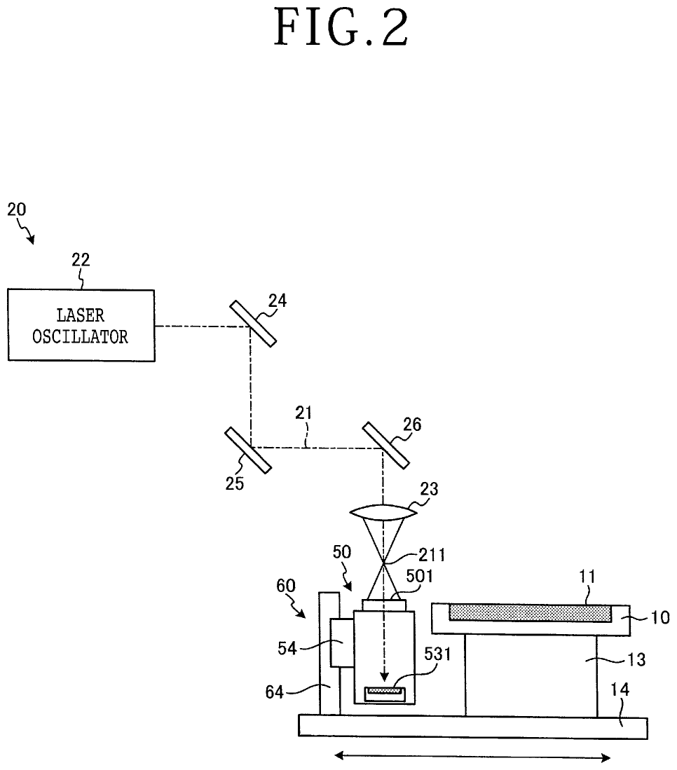

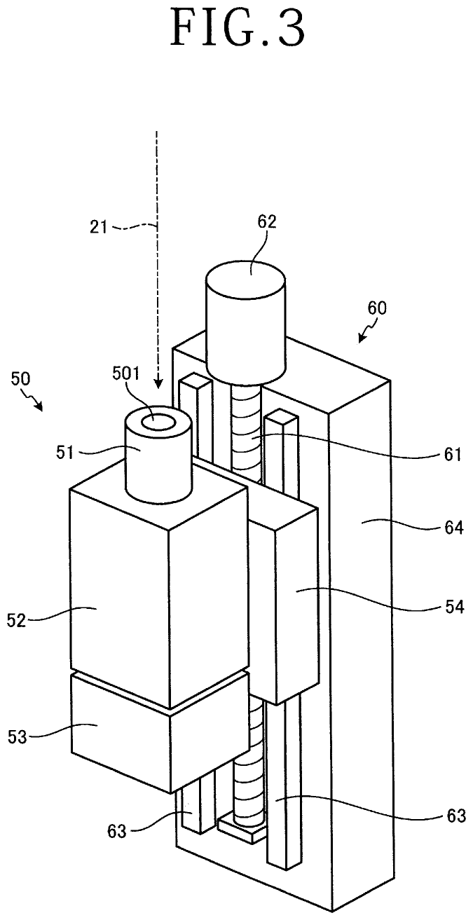

A configuration of a laser processing apparatus 1 according to an embodiment of the present invention will first be described with reference to the drawings. FIG. 1 is a perspective view illustrating an example of a configuration of the laser processing apparatus 1 according to the embodiment. FIG. 2 is a schematic diagram illustrating a general configuration of a laser beam irradiating unit 20 of the laser processing apparatus 1 illustrated in FIG. 1. FIG. 3 is a perspective view illustrating a general configuration of a measuring unit 50 of the laser processing apparatus 1 illustrated in FIG. 1.

In the following description, an X-axis direction is one direction in a horizontal plane. A Y-axis direction is a direction orthogonal to the X-axis direction in the horizontal plane. A Z-axis direction is a direction orthogonal to the X-axis direction and the Y-axis direction. The laser processing apparatus 1 according to the embodiment has the X-axis direction as a processing feed direction and has the Y-axis direction as an indexing feed direction.

As illustrated in FIG. 1, the laser processing apparatus 1 includes a chuck table 10, a laser beam irradiating unit 20, a moving unit including an X-axis direction moving unit 30 and a Y-axis direction moving unit 40, a measuring unit 50, an imaging unit 70, a display unit 80, and a control unit 90. In addition, as illustrated in FIG. 2, the laser processing apparatus 1 includes a Z-axis direction moving unit 60.

The laser processing apparatus 1 according to the embodiment is an apparatus that processes a workpiece 100 held on the chuck table 10 by irradiating the workpiece 100 with a laser beam 21 by the laser beam irradiating unit 20. The processing of the workpiece 100 by the laser processing apparatus 1 is, for example, modified layer formation processing of forming a modified layer within the workpiece 100 by stealth dicing, groove processing of forming grooves in the top surface of the workpiece 100, cutting processing of cutting the workpiece 100 along planned dividing lines, or the like.

The workpiece 100 in the embodiment is a wafer such as a semiconductor device wafer, or an optical device wafer in a disk shape which wafer has silicon (Si), sapphire (Al₂O₃), gallium arsenide (GaAs), silicon carbide (SiC), or the like as a substrate. It is to be noted that the workpiece 100 is not limited to the embodiment and may not be in a disk shape in the present invention. The workpiece 100 is, for example, supported within an opening of an annular frame 110 by affixing, to the undersurface of the workpiece 100, a tape 111 to which the annular frame 110 is affixed and which has a larger diameter than the outside diameter of the workpiece 100.

The chuck table 10 holds the workpiece 100 by a holding surface 11. The holding surface 11 has a disk shape formed of a porous ceramic or the like. The holding surface 11 in the embodiment is a flat surface parallel with a horizontal direction. The holding surface 11 is, for example, connected to a vacuum suction source via a vacuum suction path. The chuck table 10 sucks and holds the workpiece 100 mounted on the holding surface 11. A plurality of clamp units 12 that sandwich the annular frame 110 supporting the workpiece 100 are arranged on the periphery of the chuck table 10.

The chuck table 10 is rotated about an axis parallel with the Z-axis direction by a rotating unit 13. The rotating unit 13 is supported by an X-axis direction moving plate 14. The rotating unit 13 and the chuck table 10 are moved in the X-axis direction by the X-axis direction moving unit 30 via the X-axis direction moving plate 14. The rotating unit 13 and the chuck table 10 are moved in the Y-axis direction by the Y-axis direction moving unit 40 via the X-axis direction moving plate 14, the X-axis direction moving unit 30, and a Y-axis direction moving plate 15.

The laser beam irradiating unit 20 is a unit that irradiates the workpiece 100 held on the chuck table 10 with a pulsed laser beam 21. As illustrated in FIG. 2, the laser beam irradiating unit 20 includes a laser oscillator 22, a condenser 23, and mirrors 24, 25, and 26.

The laser oscillator 22 oscillates a laser having a predetermined wavelength for processing the workpiece 100, and emits the laser beam 21. The laser beam 21 applied by the laser beam irradiating unit 20 has a wavelength transmissible through or absorbable by the workpiece 100.

The condenser 23 condenses and applies the laser beam 21 emitted from the laser oscillator 22 to the workpiece 100 held on the holding surface 11 of the chuck table 10 or the measuring unit 50. The condenser 23 in the embodiment condenses the laser beam 21 guided by the mirrors 24, 25, and 26 toward the workpiece 100 or the measuring unit 50. The traveling direction of the laser beam 21 passed through the condenser 23 is parallel with the Z-axis direction.

At least the condenser 23 of the laser beam irradiating unit 20 is supported so as to be movable in the Z-axis direction by condensing point position adjusting means installed on a column 3 (see FIG. 1) erected from an apparatus main body 2 (see FIG. 1) of the laser processing apparatus 1. The condensing point position adjusting means moves a condensing point 211 of the laser beam 21 condensed by the condenser 23 in an optical axis direction perpendicular to the holding surface 11 of the chuck table 10.

The mirrors 24, 25, and 26 are provided on an optical path of the laser beam 21 between the laser oscillator 22 and the condenser 23. The mirrors 24, 25, and 26 guide the laser beam 21 emitted by the laser oscillator 22 from the laser oscillator 22 to the condenser 23. In a case where the laser beam 21 emitted from the laser oscillator 22 is the ultraviolet (UV), for example, a reflective film reflecting the UV is formed on the mirrors 24, 25, and 26.

In the embodiment, the mirror 24 reflects the laser beam 21 emitted by the laser oscillator 22 to the mirror 25. The mirror 25 reflects the laser beam 21 reflected by the mirror 24 to the mirror 26. The mirror 26 reflects the laser beam 21 reflected by the mirror 25 to the condenser 23.

As illustrated in FIG. 1, the X-axis direction moving unit 30 is a unit that moves the chuck table 10 and the laser beam irradiating unit 20 relative to each other in the X-axis direction as the processing feed direction. The X-axis direction moving unit 30 in the embodiment moves the chuck table 10 in the X-axis direction. The X-axis direction moving unit 30 in the embodiment is installed on the apparatus main body 2 of the laser processing apparatus 1.

The X-axis direction moving unit 30 supports the X-axis direction moving plate 14 so as to be movable in the X-axis direction. The X-axis direction moving unit 30 includes a well-known ball screw 31, a well-known pulse motor 32, and well-known guide rails 33. The ball screw 31 is provided so as to be rotatable about an axis. The pulse motor 32 rotates the ball screw 31 about the axis. The guide rails 33 support the X-axis direction moving plate 14 so as to be movable in the X-axis direction. The guide rails 33 are arranged in a state of being fixed to the Y-axis direction moving plate 15.

The Y-axis direction moving unit 40 is a unit that moves the chuck table 10 and the laser beam irradiating unit 20 relative to each other in the Y-axis direction as the indexing feed direction. The Y-axis direction moving unit 40 in the embodiment moves the chuck table 10 in the Y-axis direction. The Y-axis direction moving unit 40 in the embodiment is installed on the apparatus main body 2 of the laser processing apparatus 1.

The Y-axis direction moving unit 40 supports the Y-axis direction moving plate 15 so as to be movable in the Y-axis direction. The Y-axis direction moving unit 40 includes a well-known ball screw 41, a well-known pulse motor 42, and well-known guide rails 43. The ball screw 41 is provided so as to be rotatable about an axis. The pulse motor 42 rotates the ball screw 41 about the axis. The guide rails 43 support the Y-axis direction moving plate 15 so as to be movable in the Y-axis direction. The guide rails 43 are arranged in a state of being fixed to the apparatus main body 2.

The measuring unit 50 measures a beam profile of the laser beam 21. The measuring unit 50 measures the beam profile of the laser beam 21, and outputs a result of the measurement to the control unit 90. As illustrated in FIG. 2, the measuring unit 50 measures the beam profile of the laser beam 21 at a position at which the laser beam 21 is diverged after passing through the condensing point 211 of the laser beam 21. As illustrated in FIG. 3, the measuring unit 50 in the embodiment includes a microscope 51, an attenuating optical system 52, and an imaging element 53.

The microscope 51 magnifies the laser beam 21 condensed by the condenser 23 illustrated in FIG. 2. The magnification of the microscope 51 is, for example, set at 5 times or more and 100 times or less, and is set at 10 times in the embodiment. In the case where the laser beam 21 oscillated from the laser oscillator 22 is the UV, the microscope 51 includes a UV compatible microscope lens resistant to the UV.

The attenuating optical system 52 attenuates the intensity of the laser beam 21 magnified by the microscope 51. The attenuating optical system 52 attenuates the intensity of the laser beam 21 and transmits the laser beam 21 to the imaging element 53. The attenuating optical system 52, for example, includes a neutral density (ND) filter that decreases an amount of light by a certain amount, and transmits the light without selecting a wavelength in a predetermined wavelength range. It is to be noted that the attenuating optical system 52 is not limited to the above-described example but may be a plurality of prisms provided to reflect a part of the laser beam 21.

The imaging element 53 performs imaging within a predetermined visual field range. The imaging element 53 images the laser beam 21 magnified by the microscope 51 and attenuated by the attenuating optical system 52 within the visual field range. The imaging element 53 has a light receiving surface 531 parallel with the holding surface 11 of the chuck table 10. The light receiving surface 531 receives the laser beam 21 diverged after passing through the condensing point 211.

The imaging element 53, for example, includes a beam profiler that measures the beam diameter and spatial intensity distribution of the laser beam 21. The beam profiler, for example, obtains a planar image of the laser beam 21 which planar image illustrates the shape and spatial intensity distribution of the laser beam 21 by imaging the laser beam 21. The beam profiler, for example, includes a complementary metal oxide semiconductor (CMOS). It is to be noted that the imaging element 53 is not limited to the beam profiler but may be a wave front sensor that measures the wave front of the laser beam 21, that is, the beam diameter of a same phase and the intensity distribution of the laser beam 21.

The measuring unit 50 is provided so as to be adjacent to the chuck table 10. The measuring unit 50 in the embodiment is supported by the X-axis direction moving plate 14. The measuring unit 50 in the embodiment is moved in the X-axis direction by the X-axis direction moving unit 30 via the X-axis direction moving plate 14. The measuring unit 50 in the embodiment is moved in the Y-axis direction by the Y-axis direction moving unit 40 via the X-axis direction moving plate 14, the X-axis direction moving unit 30, and the Y-axis direction moving plate 15. That is, in the embodiment, the measuring unit 50 moves in the X-axis direction and the Y-axis direction together with the chuck table 10 and the rotating unit 13 (see the direction of an arrow illustrated in FIG. 2).

The measuring unit 50 is moved in the Z-axis direction by the Z-axis direction moving unit 60 via a Z-axis direction moving plate 54. The measuring unit 50 is movable in the Z-axis direction between a retreat position and a measurement position by the Z-axis direction moving unit 60. In the measuring unit 50 at the retreat position, a surface 501 on which the laser beam is incident is located below the upper surface (holding surface 11) of the chuck table 10. In the measuring unit 50 at the measurement position, the surface 501 on which the laser beam is incident is located above the upper surface (holding surface 11) of the chuck table 10. That is, the measuring unit 50 can be located at the retracted position during non-measurement, and located at the measurement position during measurement. Incidentally, the surface 501 on which the laser beam is incident in the measuring unit 50 refers to an upper end surface of the microscope 51.

The Z-axis direction moving unit 60 is a unit that moves the measuring unit 50 in the Z-axis direction as a direction perpendicular to the light receiving surface 531 of the measuring unit 50. The Z-axis direction moving unit 60 in the embodiment is installed on the X-axis direction moving plate 14.

The Z-axis direction moving unit 60 supports the Z-axis direction moving plate 54 so as to be movable in the Z-axis direction. The Z-axis direction moving unit 60 includes a well-known ball screw 61, a well-known pulse motor 62, and well-known guide rails 63. The ball screw 61 is provided so as to be rotatable about an axis. The pulse motor 62 rotates the ball screw 61 about the axis. The guide rails 63 support the Z-axis direction moving plate 54 so as to be movable in the Z-axis direction. The guide rails 63 are arranged in a state of being fixed on a column 64 erected from the X-axis direction moving plate 14.

The imaging unit 70 images the workpiece 100 held on the chuck table 10. The imaging unit 70 includes a charge coupled device (CCD) camera or an infrared camera that images the workpiece 100 held on the chuck table 10. The imaging unit 70 is, for example, fixed so as to be adjacent to the condenser 23 (see FIG. 2) of the laser beam irradiating unit 20. The imaging unit 70 images the workpiece 100, thereby obtains an image for carrying out alignment that aligns the workpiece 100 and the laser beam irradiating unit 20 with each other, and outputs the obtained image to the control unit 90.

The display unit 80 is a display unit formed by a liquid crystal display apparatus or the like. The display unit 80, for example, displays, on a display surface, a processing condition setting screen, the state of the workpiece 100 imaged by the imaging unit 70, the state of processing operation, and the like. In a case where the display surface of the display unit 80 includes a touch panel, the display unit 80 may include an input unit. The input unit can receive various kinds of operations such as registration of processing content information by an operator. The input unit may be an external input apparatus such as a keyboard. Information or an image displayed on the display surface of the display unit 80 is changed by an operation from the input unit or the like. The display unit 80 may include a notifying device. The notifying device notifies predetermined notification information to the operator of the laser processing apparatus 1 by emitting at least one of sound and light. The notifying device may be an external notifying device such as a speaker, or a light emitting apparatus.

The control unit 90 makes the laser processing apparatus 1 perform processing operation on the workpiece 100 by controlling each of the above-described constituent elements of the laser processing apparatus 1. The control unit 90 controls the laser beam irradiating unit 20, the X-axis direction moving unit 30, the Y-axis direction moving unit 40, the measuring unit 50, the Z-axis direction moving unit 60, the imaging unit 70, and the display unit 80.

The control unit 90 is a computer including an arithmetic processing apparatus as arithmetic means, a storage apparatus as storing means, and an input-output interface apparatus as communicating means. The arithmetic processing apparatus, for example, includes a microprocessor such as a central processing unit (CPU). The storage apparatus has a memory such as a read only memory (ROM), and a random access memory (RAM). The arithmetic processing apparatus performs various kinds of operation on the basis of a predetermined program stored in the storage apparatus. The arithmetic processing apparatus controls the laser processing apparatus 1 by outputting various kinds of control signals to the above-described constituent elements via the input-output interface apparatus according to a result of the operation.

The control unit 90, for example, makes the imaging unit 70 image the workpiece 100. The control unit 90, for example, performs image processing on an image imaged by the imaging unit 70. The control unit 90, for example, detects a processing line of the workpiece 100 by the image processing. The control unit 90, for example, drives the X-axis direction moving unit 30 so as to move a processing point as the condensing point 211 of the laser beam 21 along the processing line, and makes the laser beam irradiating unit 20 apply the laser beam 21.

The control unit 90, for example, moves the measuring unit 50 to the measurement position or the retracted position by driving the Z-axis direction moving unit 60. The control unit 90 makes the measuring unit 50 measure the beam profile of the laser beam 21 in optional timing. The control unit 90, for example, obtains measurement data on the beam profile of the laser beam 21 from the measuring unit 50. The control unit 90 includes a storage section 91, a comparing section 92, and a notifying section 93.

The storage section 91 stores the position of the laser beam 21 applied to the light receiving surface 531 of the imaging element 53 of the measuring unit 50. The position of the laser beam 21 which position is stored by the storage section 91 is, for example, a position measured by using the measuring unit 50 at a time of an apparatus start-up of the laser processing apparatus 1, a time of an end of calibration of the laser beam irradiating unit 20, or the like. That is, the position of the laser beam 21 which position is stored by the storage section 91 indicates a desired beam shape.

The comparing section 92 compares the position of the laser beam 21 which position is stored in the storage section 91 with the position of the laser beam 21 which position is measured in predetermined timing. The position of the laser beam 21 which position is measured in the predetermined timing is a position measured by using the measuring unit 50 during the processing of the workpiece 100 or at a time of idling, a time of maintenance, or the like.

The notifying section 93 notifies a warning when the position of the laser beam 21 which position is compared by the comparing section 92 is changed by a predetermined value or more. The warning, for example, includes warning information that prompts the operator for calibration. The notifying section 93, for example, makes the notifying device of the display unit 80 notify predetermined warning information.

Incidentally, functions of the storage section 91 are implemented by the storage apparatus of the control unit 90 described above. In addition, functions of the comparing section 92 and the notifying section 93 are implemented by the arithmetic processing apparatus of the control unit 90 described above by executing the program stored in the storage apparatus.

As described above, in the laser processing apparatus 1 according to the embodiment, the measuring unit 50 that measures the beam profile of the laser beam 21 is provided so as to be adjacent to the chuck table 10 that holds the workpiece 100. Thus, a space saving can be achieved, so that an increase in size of the apparatus can be suppressed. In addition, because the measuring unit 50 is provided so as to be adjacent to the chuck table 10 that holds the workpiece 100, the beam profile can be measured at a time of channel switching or at each end of processing of a predetermined number of processing lines, for example, even during the processing of the workpiece 100.

In addition, mirrors for reflecting the laser beam 21 and guiding the laser beam 21 to the measuring unit 50 are not necessary. This leads to a cost reduction, simplifies adjustment, and contributes to the shortening of downtime. Hence, the laser processing apparatus 1 can measure a beam shape easily and safely.

It is to be noted that the present invention is not limited to the foregoing embodiment. For example, the measuring unit 50 may be successively moved in the Z-axis direction, and the state of the laser beam 21 may be measured and stored by through focus. That is, a three-dimensional beam profile including aberration at midpoints of the laser beam 21 may be obtained.

In addition, the Z-axis direction moving unit 60 is not limited to the configuration including the ball screw 61 and the pulse motor 62 in the embodiment but may be of a configuration including an air cylinder.

In addition, in a case where the condenser 23 is a long-focus condensing lens, and the condensing point position adjusting means for moving the condenser 23 in a condensing point position adjusting direction (Z-axis direction) is provided, the Z-axis direction moving unit 60 that moves the measuring unit 50 in the Z-axis direction does not have to be provided. That is, the measuring unit 50 may be fixed relative to the apparatus main body 2 or the chuck table 10. Incidentally, in a case where the condenser 23 is a condensing lens having a high numerical aperture (NA), a work distance is small, and therefore the Z-axis direction moving unit 60 that moves the measuring unit 50 in the Z-axis direction is necessary in order to prevent interference with peripheral structures.

The present invention is not limited to the details of the above described preferred embodiment. The scope of the invention is defined by the appended claims and all changes and modifications as fall within the equivalence of the scope of the claims are therefore to be embraced by the invention.

What is claimed is:

1. A laser processing apparatus comprising:
a chuck table having a holding surface configured to hold a workpiece;
a laser beam irradiating unit having a condenser configured to condense and apply a laser beam to the workpiece held on the chuck table;
a moving unit configured to move the chuck table and a condensing point of the laser beam relative to each other;
a measuring unit configured to measure a beam profile of the laser beam; and
a control unit configured to control each of the units,
the measuring unit being disposed adjacent to the chuck table so as to have a light receiving surface parallel with the holding surface of the chuck table.

2. The laser processing apparatus according to claim 1, wherein
the control unit includes
a storage section configured to store a position of the laser beam applied to the light receiving surface,
a comparing section configured to compare the position of the laser beam, the position being stored in the storage section, with a position of the laser beam measured in predetermined timing, and
a notifying section configured to notify a warning when the position of the laser beam, the position being compared by the comparing section, is changed by a predetermined value or more.

3. The laser processing apparatus according to claim 1, further comprising:
a Z-axis direction moving unit configured to move the measuring unit in a Z-axis direction as a direction perpendicular to the light receiving surface.

4. The laser processing apparatus according to claim 1, wherein
the measuring unit is located at a retreat position at which a surface on which the laser beam is incident is located below an upper surface of the chuck table during non-measurement, and
the measuring unit is located at a measurement position at which the surface on which the laser beam is incident is located above the upper surface of the chuck table during measurement.
